(19) United States
(12) Patent Application Publication
(10) Pub. No.: US 2026/0291468 A1
(43) Pub. Date: Sep. 24, 2026

(54) TUNABLE TRANSCONDUCTANCE-CAPACITANCE FILTER

(71) Applicant: QUALCOMM Incorporated, San Diego, CA (US)

(72) Inventors: Mehran BAKHSHIANI, San Diego, CA (US); Youssef Osama HASSAN, Irvine, CA (US); Timothy Donald GATHMAN, San Diego, CA (US); Aleksandar Miodrag TASIC, San Diego, CA (US)

(21) Appl. No.: 19/088,574

(22) Filed: Mar. 24, 2025

(51) Int. Cl. H03H 11/12; H03F 3/24; H04B 1/16

(52) U.S. Cl. CPC H03H 11/126; H04B 1/16; H03F 3/245; H03F 2200/165; H03F 2200/171

(57) ABSTRACT

In some aspects, a filter circuit may include an input stage comprising a resistor-capacitor (RC) circuit configured to receive an input voltage and convert the input voltage to an input current. The filter circuit may include a current mirror stage comprising a transistor network and one or more differential capacitors configured to receive the input current and apply a gain to the input current to generate an output current. The filter circuit may include an output stage comprising an output capacitor coupled between an output from the current mirror stage and an input to an analog-to-digital converter (ADC) to maintain the output current.

### FIELD OF THE DISCLOSURE

Aspects of the present disclosure generally relate to wireless transceivers, and to a tunable transconductance-capacitance filter in a wireless receiver.

### BACKGROUND

Wireless devices often include a transceiver to communicate over a wireless link. For example, a wireless transceiver is an integrated device that combines wireless transmission and wireless reception functionalities. The transmit chain in a transceiver typically includes a baseband signal processor that modulates a baseband signal, and a mixer that up-converts the modulated signal to prepare the baseband signal for radio frequency (RF) transmission. The up-converted signal is then amplified by a power amplifier to increase a strength of the signal before the signal is sent to an antenna that converts the signal into electromagnetic waves that propagate through the air to an intended receiver. On the receive side, the antenna captures and converts incoming electromagnetic waves into electrical signals that are provided to a receive chain. The receive chain typically includes a low-noise amplifier (LNA) that amplifies the received signal to enhance signal strength and reduce noise. The amplified signal is then down-converted to a lower frequency by a mixer, and subjected to further amplification and demodulation by a baseband processor to retrieve the original data.

### SUMMARY

In some implementations, a baseband filter includes a transimpedance amplifier to receive a down-converted radio frequency (RF) signal and to filter and amplify the down-converted RF signal; a filter configured to receive the amplified down-converted RF signal and to filter the amplified down-converted RF signal to remove undesired frequency components from a desired baseband signal, wherein the filter comprises: a first stage, associated with a first pole, to convert an input voltage associated with the amplified down-converted RF signal to an input current; a second stage, associated with a second pole, to apply a gain to the input current to generate an output current; and a third stage, associated with a third pole, to maintain the output current and provide the desired baseband signal to an analog-to-digital converter (ADC); and a programming interface to receive one or more instructions to tune one or more of the first pole, the second pole, the third pole, or the gain applied to the input current based on a frequency associated with the down-converted RF signal.

In some implementations, a filter includes an input stage comprising a resistor-capacitor (RC) circuit configured to receive an input voltage and convert the input voltage to an input current; a current mirror stage comprising a transistor network and one or more differential capacitors configured to receive the input current and apply a gain to the input current to generate an output current; and an output stage comprising an output capacitor coupled between an output from the current mirror stage and an input to an ADC to maintain the output current.

In some implementations, a method includes receiving a down-converted RF signal at a circuit; programming a gain associated with the circuit according to a first frequency associated with the down-converted RF signal; and filtering, by the circuit, the down-converted RF signal to remove undesired frequency components from a desired baseband signal associated with a second frequency, wherein filtering the down-converted RF signal includes: converting, at a transconductance (gm) stage of the circuit, an input voltage associated with the down-converted RF signal to an input current; applying, at a current mirror (cm) stage of the circuit, the programmed gain to the input current to generate an output current; and providing, at a capacitance (c) stage of the circuit, capacitance to maintain the output current for the desired baseband signal; and providing, by the circuit, the desired baseband signal associated with the second frequency to an ADC.

Aspects generally include an apparatus, a method, a system, a wireless communication device, a transceiver, a receiver, a filter, and/or a circuit, as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example environment with an electronic device that includes a wireless interface, in accordance with the present disclosure.

FIG. 2 is a diagram illustrating an example wireless transceiver, in accordance with the present disclosure.

FIG. 3 is a diagram illustrating example receiver hardware that includes an operational amplifier feedback topology, in accordance with the present disclosure.

FIG. 4 is a diagram illustrating example receiver hardware that includes a tunable baseband filter, in accordance with the present disclosure.

FIG. 5 is a diagram illustrating example receiver hardware that includes a tunable transconductance-capacitance filter, in accordance with the present disclosure.

FIGS. 6A-6D are diagrams illustrating example tunable transconductance-capacitance filters that may be used in a wireless receiver, in accordance with the present disclosure.

FIG. 7 is a diagram illustrating an example beamforming architecture that may include a tunable transconductance-capacitance filter in a receive path, in accordance with the present disclosure.

FIG. 8 is a flowchart illustrating an example method for filtering a signal in a wireless receive path, in accordance with the present disclosure.

### DETAILED DESCRIPTION

Various aspects of the present disclosure are described hereinafter with reference to the accompanying drawings. However, aspects of the present disclosure may be embodied in many different forms and is not to be construed as limited to any specific aspect illustrated by or described with reference to an accompanying drawing or otherwise presented in this disclosure. Rather, these aspects are provided so that this disclosure will be thorough and complete, and will fully convey the scope of the disclosure to those skilled in the art. One skilled in the art may appreciate that the scope of the disclosure is intended to cover any aspect of the disclosure disclosed herein, whether implemented independently of or in combination with any other aspect of the disclosure. For example, an apparatus may be implemented or a method may be practiced using various combinations or quantities of the aspects set forth herein. In addition, the scope of the disclosure is intended to cover an apparatus having, or a method that is practiced using, other structures and/or functionalities in addition to or other than the structures and/or functionalities with which various aspects of the disclosure set forth herein may be practiced. Any aspect of the disclosure disclosed herein may be embodied by one or more elements of a claim.

In a wireless receiver, various components may be implemented with a super-heterodyne architecture or a direct-conversion architecture to convert a high-frequency radio frequency (RF) signal to a baseband frequency suitable for digital signal processing. More particularly, a super-heterodyne architecture generally includes various components that are configured to convert a signal from an RF to a baseband frequency in multiple stages (e.g., from the RF to an intermediate frequency (IF) in a first stage, and then from the IF to the baseband frequency in a second stage), and a direct-conversion architecture includes various components configured to convert a signal from an RF to a baseband frequency in one stage. For example, in a typical receive signal path, an RF signal received via one or more antennas may be amplified by a low noise amplifier (LNA), and the amplified RF signal may be mixed with a receive local oscillator (LO) signal to down-convert the RF signal to the baseband frequency. The baseband signal may then be filtered (e.g., to remove noise or other undesired frequency components) and provided to an analog-to-digital converter (ADC) that may convert the baseband signal to digital in-phase and quadrature (I/Q) signals for digital signal processing. For example, in some wireless receiver architectures, the baseband signal may be filtered using a multi-stage baseband filter that includes an operational amplifier (op-amp) resistance-capacitance (RC) feedback topology.

However, in some cases, the wireless receiver may support communication using multiple carrier frequencies that are associated with different gain modes, and some hardware in the wireless receive path may be used only in high gain modes. For example, when a high gain is not needed to process a received RF signal, the wireless receive path may bypass the LNA and/or one or more amplification stages in the baseband filter. For example, a baseband filter with an op-amp RC feedback topology may include multiple transimpedance amplifiers (TIAs), such as a first TIA that provides first-order filtering, a second TIA that provides second-order filtering, and a third TIA that provides third-order filtering, and the second and third TIA may be bypassed in one or more gain modes associated with a relatively low gain. Accordingly, all of the hardware in the wireless receive path is used only in one or more high gain modes, and only a subset of the hardware in the wireless receive path is used in the one or more low gain modes. However, the hardware that is unused (e.g., bypassed) in the low gain modes tends to occupy a large area in an op-amp RC feedback topology.

Some aspects described herein relate to a tunable transconductance-capacitance filter in a wireless receiver. Some aspects more specifically relate to a baseband filter in a wireless receiver, where the baseband filter may include an initial TIA stage followed by one or more transconductance (gm) stages associated with a programmable gain. For example, in some aspects, the one or more gm stages may provide current-based filtering, where an output voltage from the initial TIA stage may be converted to an input current and a programmable gain may be applied to the input current according to an active gain mode. In some aspects, the one or more gm stages may provide second-order and third-order filtering that may be used in one or more high gain modes, which may reduce an area associated with the baseband filter by more than 70% relative to a baseband filter that uses two-stage or three-stage op-amp-based RC filters in the one or more high gain modes. Furthermore, because the one or more gm stages follow the initial TIA stage, an interface between a mixer and the initial TIA stage may be unchanged, such that the presence of the one or more gm stages is transparent in low gain modes. Furthermore, by using gm structures and current-based filtering, the tunable transconductance-capacitance filter may support larger bandwidths that may be used for some time division duplexing (TDD) carriers. For example, baseband filters with op-amp based feedback topologies tend to support only up to 200 megahertz (MHz) bandwidths in sub-6 gigahertz (GHz) bands. In contrast, by using gm structures and current-based filtering, some aspects described herein may support expanded bandwidths (e.g., 1 GHz or higher) that may be used in more advanced (e.g., 6G) wireless networks. For example, as described herein, a circuit that follows a TIA in a wireless receiver may provide three poles and a zero that can be individually tuned to optimize a third-order intercept point (IP3), filter rejection, and/or droop over a band edge for different operational bandwidths. Accordingly, some aspects described herein may provide significant area reduction and performance improvements over baseband filters that use op-amp RC feedback topologies to provide second-order and third-order filtering in high gain modes. For example, some aspects described herein may use a filter with differential capacitors, which occupy significantly less area than capacitors used in traditional op-amp RC filters. In addition, some aspects described herein provide a filter with three or more independent poles, in contrast to op-amp RC filters that only allow second-order poles per op-amp. Furthermore, op-amps occupy a significantly larger active area than the gm-based structure described herein.

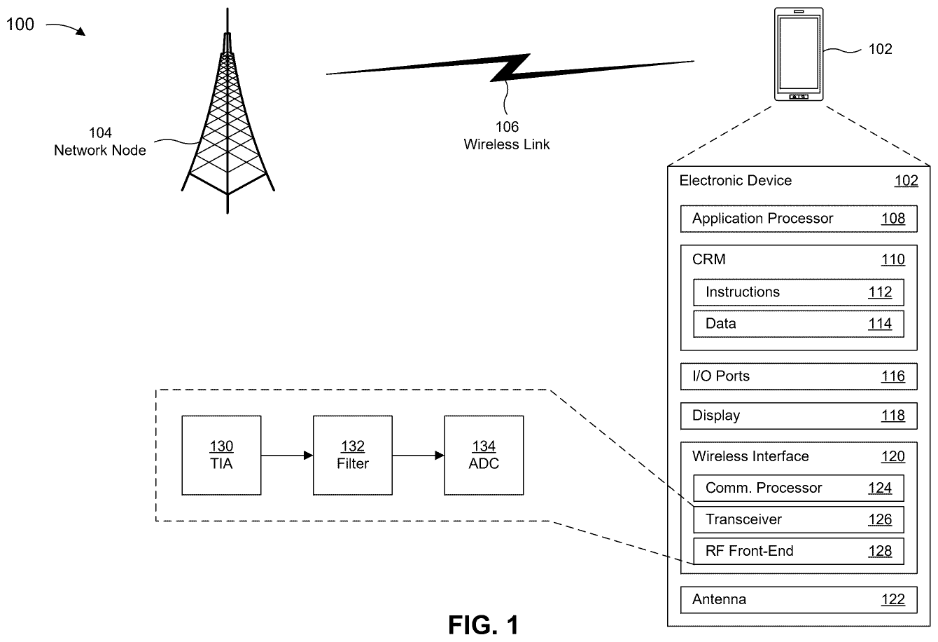

FIG. 1 is a diagram illustrating an example environment 100 with an electronic device 102 that includes a wireless interface 120, in accordance with the present disclosure. In some aspects, as described in further detail elsewhere herein, the wireless interface 120 may include one or more components in a receive path, such as a TIA 130 that may amplify an analog signal, a filter 132 that may filter the analog signal to remove one or more unwanted frequency components, and an ADC 134 that may convert the analog signal to a digital signal suitable for digital signal processing.

In the example environment 100, the electronic device 102 may communicate with a network node 104 through a wireless link 106. For example, the network node 104 may include one or more devices, components, or systems that enable communication between the electronic device 102 and one or more devices, components, or systems in the environment 100. The network node 104 may be, may include, or may also be referred to as a base station, a New Radio (NR) network node, a 5G network node, a 6G network node, a Node B, an eNB, a gNB, an access point (AP), a transmission reception point (TRP), a mobility element, a core network entity, a network element, a network equipment, a radio unit (RU), a distributed unit (DU), a central unit (CU), and/or another suitable device that supports wireless communication.

In some aspects, the electronic device 102 may be any suitable computing device or other electronic device. For example, the electronic device 102 may be a smartphone, a cellular base station, a broadband router, an AP, a cellular or mobile phone, a user equipment (UE), a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, a fitness management device, a wearable device such as smart glasses or a smartwatch, a wireless power device (transmitter or receiver), a medical device, or the like.

The network node 104 may communicate with the electronic device 102 via the wireless link 106, which may be implemented as any suitable wireless link that carries a wireless communication signal. For example, the wireless link 106 may be implemented in a wireless network, which may include a cellular network, a public land mobile network (PLMN), a wireless local area network (WLAN), a wide area network (WAN), a metropolitan area network (MAN), a telephone network (e.g., the Public Switched Telephone Network (PSTN)), a private network, an ad hoc network, an intranet, a wireless personal area network (WPAN), and/or a combination of these or other networks. Although depicted as a base station tower in a cellular radio access network, the network node 104 may represent or be implemented as another device, such as a satellite, a terrestrial broadcast tower, an AP, a peer-to-peer device, a mesh network node, another electronic device as described above generally, or the like. Furthermore, although the electronic device 102 is depicted as communicating with the network node 104 via the wireless link 106, the electronic device 102 may communicate with the network node 104 or another device via a wired and/or wireless connection.

The wireless link 106 may include a downlink for communicating data or control information from the network node 104 to the electronic device 102, an uplink for communicating data or control information from the electronic device 102 to the network node 104, a sidelink for communicating data or control information from the electronic device 102 to the network node 104 or vice versa, or any suitable combination thereof. The wireless link 106 may be implemented using any suitable communication protocol or standard, such as a 3rd Generation Partnership Project Long-Term Evolution (3GPP) standard, such as a 4th Generation (4G), a 5th Generation (5G), a 6th Generation (6G), or another wireless communication standard, an Institute of Electrical and Electronics Engineers (IEEE) 802.11 or IEEE 802.16 standard, a Bluetooth standard, or the like. In some aspects, the wireless link 106 may wirelessly provide power instead of or in addition to communication signaling, and the electronic device 102 or the network node 104 may be a power source or a power sink.

As shown in FIG. 1, the electronic device 102 may include at least one application processor 108 and at least one computer-readable storage medium 110. The application processor 108 may include any suitable processor, such as a central processing unit (CPU) or a multicore or graphics processor, configured to execute processor-executable instructions (e.g., code) stored by the computer-readable storage medium 110. The computer-readable storage medium 110 may include any suitable data storage media, such as volatile memory (e.g., random-access memory (RAM)), non-volatile memory, optical media, magnetic media (e.g., disk or tape), or the like. The computer-readable storage medium 110 may be implemented to store instructions 112, data 114, or other suitable information, and therefore the computer-readable storage medium 110 does not include transitory propagating signals or carrier waves.

As shown in FIG. 1, the electronic device 102 may include one or more input/output (I/O) ports 116 and at least one display 118. The I/O ports 116 may enable data exchanges or interaction with other devices, networks, or users. The I/O ports 116 may include serial ports (e.g., universal serial bus (USB) ports), parallel ports, audio ports, infrared (IR) ports, camera or other sensor ports, or the like. The display 118 may include a display screen or a projection that may present one or more graphical images provided by the electronic device 102, such as a user interface associated with an operating system, program, or application. Additionally, or alternatively, the display 118 may be implemented as a display port or a virtual interface through which graphical content of the electronic device 102 is communicated or presented.

As described herein, the electronic device 102 may include at least one wireless interface 120 and at least one antenna 122, which may be coupled one to another. The wireless interface 120 may provide connectivity to respective networks and peer devices via a wireless link, which may be configured in a manner that is similar to or different from the wireless link 106. Additionally, or alternatively, the electronic device 102 may include a wired interface device, such as an Ethernet or fiber optic transceiver for communicating over a wired local area network (LAN), an intranet, or the Internet. The wireless interface 120 may facilitate communication over any suitable type of wireless network, such as a WLAN, a WPAN, a peer-to-peer (P2P) network, a mesh network, a cellular network, a wireless wide area network (WWAN), and/or a navigational network (e.g., a Global Navigation Satellite System (GNSS)). The electronic device 102 may communicate various data and control information bidirectionally with a cellular network via the network node 104 using the wireless interface 120. Additionally, or alternatively, the electronic device 102 may communicate directly with peer devices, an alternative wireless network, or the like using the wireless interface 120.

As shown in FIG. 1, the wireless interface 120 may include at least one communication processor 124, at least one transceiver 126, and optionally at least one radio-frequency front-end (RFFE) 128. The communication processor 124 may be coupled to the transceiver 126, and the transceiver 126 may be coupled to the antenna 122, optionally through the RFFE 128 in some configurations. The communication processor 124 can also be directly coupled to the RFFE 128. In some examples, the communication processor 124 is implemented in a chip (or system-on-chip (SoC)) separate from a chip in which the transceiver 126 is implemented. Further, the RFFE 128 may be implemented in one or more chips or modules separate from the communication processor 124 and/or the transceiver 126. The communication processor 124, the transceiver 126, and the RFFE 128 may process data information, control information, and/or signals associated with communicating information via the antenna 122.

The communication processor 124 may be implemented as part of an SoC, as a modem baseband processor, or as a baseband processor (BBP) that may realize a digital communication interface for data, voice, messaging, or other applications. The communication processor 124 may include a digital signal processor (DSP) or one or more signal-processing blocks (not shown) for encoding and modulating data for transmission and for demodulating and decoding received data. Additionally, or alternatively, the communication processor 124 may manage (e.g., control or configure) aspects or operation of the transceiver 126, the RFFE 128, and/or other components of the wireless interface 120 to implement various communication protocols or communication techniques.

In some aspects, the application processor 108 and the communication processor 124 may be combined into one module or integrated circuit (IC), such as an SoC. The application processor 108 or the communication processor 124 may be operatively coupled to one or more other components, such as the computer-readable storage medium 110 or the display 118. The operative coupling may enable control over, or other interaction with, other components of the electronic device 102 by at least one processor. Additionally, the communication processor 124 may include a memory, such as the computer-readable storage medium, 110, to store data and processor-executable instructions (e.g., code). The various components illustrated in FIG. 1 and/or the other drawings using separate schematic blocks may be manufactured or packaged in different discrete manners. For example, one physical module may include components of the RFFE 128 and some components of the transceiver 126, and another physical module may combine the communication processor 124 with the remaining components of the transceiver 126. Further, the antenna 122 may be co-packaged with at least some components of the RFFE 128 or the transceiver 126.

The transceiver 126 may include circuitry and logic for filtering, amplification, channelization, and/or frequency translation. The frequency translation may include an up-conversion or a down-conversion of frequency that is performed in a single conversion operation (e.g., with a direct-conversion architecture) or through multiple conversion operations (e.g., with a super-heterodyne architecture) using one or more mixers. Accordingly, the transceiver 126 may include one or more filters, switches, amplifiers, mixers, and/or other suitable components for routing and conditioning signals that are transmitted or received via the antenna 122. In some aspects, the wireless interface 120 can include a digital-to-analog converter (DAC) (not explicitly shown in FIG. 1) and/or the ADC 134 to convert between analog signals and digital signals. The DAC and/or the ADC 134 can be implemented as part of the communication processor 124, as part of the transceiver 126, or separately from both.

In some aspects, the transceiver 126 may include one or more configurable components that may be controlled by the communication processor 124 to implement communications in various modes, with different frequency bands, or to comport with a particular wireless standard. The components or circuitry of the transceiver 126 can be implemented in any suitable fashion, such as with combined transceiver logic or separately as respective transmitter and receiver entities. In some cases, the transceiver 126 may be implemented with multiple or different sections to implement respective transmitting and receiving operations (e.g., to implement separate transmit and receive chains or paths). The transceiver 126 may also include logic to perform I/Q operations, such as synthesis, phase correction, modulation, and/or demodulation.

In some aspects, the RFFE 128 may generally include one or more filters, switches, amplifiers, phase shifters, and/or other suitable components for conditioning signals received via the antenna 122 and/or for conditioning signals to be transmitted via the antenna 122. In some aspects, the RFFE 128 may also include other RF sensors and components, such as a peak detector, a power meter, a gain control block, an antenna tuning circuit, a diplexer, a balun, or the like. In some aspects, the RFFE 128 may include one or more configurable components, such as a phase shifter or a mixer, that may be controlled by the communication processor 124 to implement communications in various modes, with different frequency bands, or using beamforming. The RFFE 128 may be coupled to the antenna 122, which may be implemented as at least one individual antenna, as at least one antenna array that includes multiple antenna elements, or as at least one antenna element of an antenna array. Accordingly, as used herein, the term “antenna” can refer to an individual antenna, an antenna array, or an antenna element of an antenna array.

In some aspects, the TIA 130 may be configured to receive a down-converted RF signal and to filter and amplify the down-converted RF signal, and the filter 132 may be configured to receive the amplified down-converted RF signal and to filter the amplified down-converted RF signal to remove undesired frequency components from a desired baseband signal. For example, in some aspects, the filter 132 may include a first stage, associated with a first pole, to convert an input voltage associated with the amplified down-converted RF signal to an input current, a second stage, associated with a second pole, to apply a gain to the input current to generate an output current, and a third stage, associated with a third pole, to maintain the output current and provide the desired baseband signal to the ADC 134. In addition, the filter 132 may include a programming interface to receive one or more instructions (e.g., from the communication processor 124 or another suitable component) to tune one or more of the first pole, the second pole, the third pole, or the gain applied to the input current based on a frequency associated with the down-converted RF signal.

As indicated above, FIG. 1 is provided as an example. Other examples may differ from what is described with regard to FIG. 1.

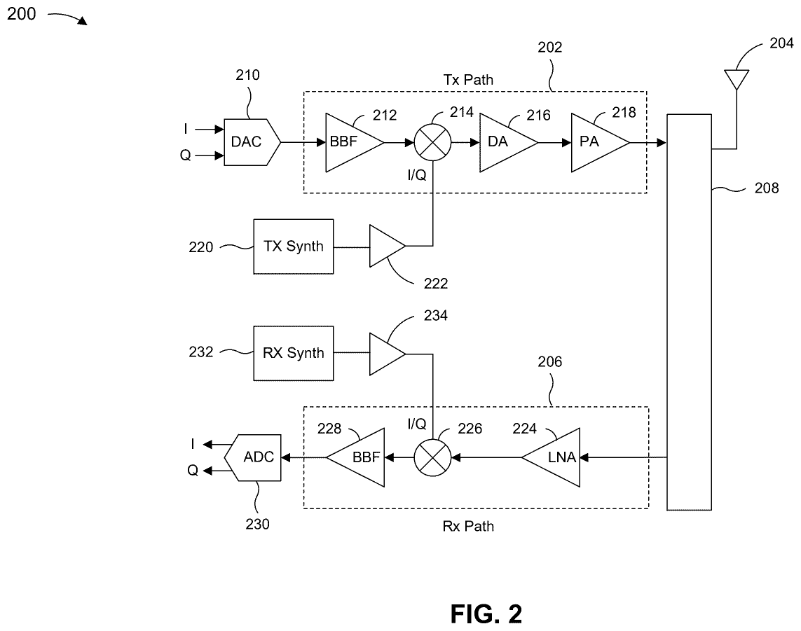

FIG. 2 is a diagram illustrating an example transceiver 200, in accordance with the present disclosure. The transceiver may be included in the wireless interface 120 shown in FIG. 1, for example in the transceiver 126 and/or the RFFE 128. As shown in FIG. 2, the transceiver 200 includes a transmit (Tx) path 202 (also known as a transmit chain) for transmitting signals via one or more antennas and a receive (Rx) path 206 (also known as a receive chain) for receiving signals via the antennas. When the Tx path 202 and the Rx path 206 share an antenna 204 (which may be an example of the antenna 122), the Tx path 202 and the Rx path 206 may be connected with the antenna 204 via an interface 208, which may include any of various suitable RF devices, such as a duplexer, a switch, and/or a diplexer, among other examples.

As shown in FIG. 2, a DAC 210 may receive in-phase (I) and quadrature (Q) baseband digital signals, which may be converted to baseband analog signals. As further shown in FIG. 2, the Tx path 202 may include a BBF 212, a mixer 214, a DA 216, and a power amplifier (PA) 218. The BBF 212, the mixer 214, and the DA 216 may be included in a radio frequency integrated circuit (RFIC), while the PA 218 may be external to the RFIC in some configurations and included in the RFIC in other configurations. The BBF 212 may filter the baseband analog signals received from the DAC 210, and the mixer 214 may mix the filtered baseband signals with a transmit LO signal to convert the baseband signal to a target frequency (e.g., to up-convert from a baseband frequency to RF). The frequency conversion process may produce sum and difference frequencies of the LO frequency and the target frequency. The sum and difference frequencies are sometimes known as beat frequencies. The beat frequencies are typically in the RF range, such that the signals output by the mixer 214 are typically RF signals, which may be amplified by the DA 216 and/or by the PA 218 before transmission by the antenna 204. In some aspects, the mixer 214 may provide a symmetrical frequency response.

As further shown in FIG. 2, the Rx path 206 may include an LNA 224, a mixer 226, and a baseband filter (BBF) 228, among other examples. The LNA 224, the mixer 226, and the BBF 228 may be included in an RFIC, which may or may not be the same RFIC that includes the components of the Tx path 202. RF signals received via the antenna 204 may be amplified by the LNA 224, and the mixer 226 may mix the amplified RF signals with a receive LO signal to convert (e.g., down-convert) the RF signal to a different baseband frequency. The baseband signals output by the mixer 226 may be filtered by the BBF 228 before being converted by an ADC 230 to digital I/Q signals for digital signal processing. In some aspects, the ADC 230 is an example of the ADC 134 illustrated in FIG. 1.

The output of an LO should remain relatively stable in frequency. However, tuning the LO to different frequency typically entails using a variable-frequency oscillator, which may involve compromises between stability and tunability. In some cases, frequency synthesizers with a voltage-controlled oscillator (VCO) may be used to generate a stable, tunable LO with a particular tuning range. For example, as shown in FIG. 2, the transmit LO frequency may be produced by a Tx frequency synthesizer 220, which may be buffered or amplified by amplifier 222 before being mixed with the baseband signals in the mixer 214. Similarly, the receive LO frequency may be produced by an Rx frequency synthesizer 232, which may be buffered or amplified by amplifier 234 before being mixed with the RF signals in the mixer 226.

In some aspects, the BBF 228 may include a TIA configured to receive (e.g., from the mixer 226) a down-converted RF signal and to filter and amplify the down-converted RF signal, and a filter configured to receive the amplified down-converted RF signal and to filter the amplified down-converted RF signal to remove undesired frequency components from a desired baseband signal. For example, in some aspects, the filter may include an input stage comprising an RC circuit configured to receive an input voltage and convert the input voltage to an input current; a current mirror stage comprising a transistor network and one or more differential capacitors configured to receive the input current and apply a gain to the input current to generate an output current; and an output stage comprising an output capacitor coupled between an output from the current mirror stage and an input to the ADC 230 to maintain the output current. In some aspects, the TIA and the filter(s) in the BBF 228 described above are examples of the TIA 130 and the filter 132 illustrated in FIG. 1. In addition, in some aspects, the BBF 228 may include a programming interface to receive one or more instructions to tune one or more of the first pole, the second pole, the third pole, or the gain applied to the input current based on a frequency associated with the down-converted RF signal.

As indicated above, FIG. 2 is provided as an example. Other examples may differ from what is described with regard to FIG. 2.

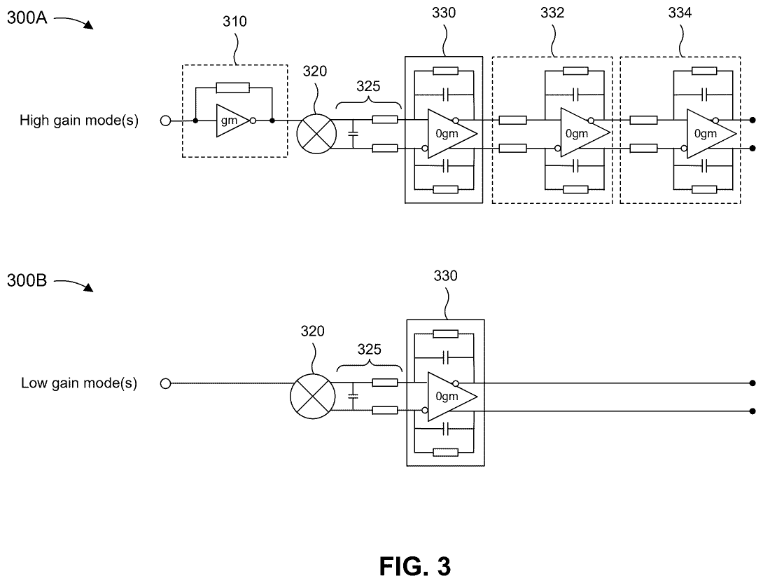

FIG. 3 is a diagram illustrating example receiver hardware that includes an operational amplifier feedback topology, in accordance with the present disclosure. For example, as shown in FIG. 3, the receiver hardware may include an LNA 310 that may be implemented using a TIA architecture that may convert an input current to a voltage. For example, as shown in FIG. 3, the LNA 310 may include an operational amplifier (op-amp) with a feedback resistor coupled between an input to and an output from the op-amp, where a resistance value of the feedback resistor sets the gain of the LNA 310. In some aspects, the LNA 310 may be coupled to one or more antennas and may amplify an RF signal received via the one or more antennas. As further shown in FIG. 3, the amplified signal may be provided from the LNA 310 to a mixer 320, which may down-convert the received RF signal using inputs from one or more LOs to create intermediate or baseband signals that carry encoded and modulated information. The output from the mixer 320 may then be input to a baseband filter that includes an op-amp based feedback topology.

For example, as shown in FIG. 3, the baseband filter may include a passive filter 325, a TIA 330, a first op-amp based active RC filter 332, and a second op-amp based active RC filter 334. As described herein, the passive filter 325 and the TIA 330, the first op-amp based active RC filter 332, and the second op-amp based active RC filter 334 respectively provide first-order, second-order, and third-order filtering to generate a baseband signal that may then be input into an ADC for conversion to digital signals for baseband processing, such as decoding, de-interleaving, or similar operations. For example, as shown in FIG. 3, the passive filter 325, the first op-amp based active RC filter 332, and the first op-amp based active RC filter 334 are each implemented with a pair of resistors coupled between positive and negative inputs and outputs from a previous stage (e.g., the mixer 320 is the previous stage for the passive filter 325, the TIA 330 is the previous stage for the first op-amp based active RC filter 332, and the first op-amp based active RC filter 332 is the previous stage for the second op-amp based active RC filter 334). As further shown, the passive filter 325 additionally includes a capacitor coupled between the pair of the resistors and outputs from the mixer 320. In addition, the TIA 330 and the op-amp based active RC filters 332, 334 each include a first feedback resistor and a first feedback capacitor (or first RC feedback circuit) coupled between a positive input node and a positive output node and a second feedback resistor and a second feedback capacitor (or second RC feedback circuit) coupled between a negative input node and a negative output node. In some aspects, the mixer 320 may receive an RF signal, and an output from the mixer 320 is a down-converted RF signal that includes a desired down-converted portion and an undesired up-converted portion. Accordingly, the baseband filter (e.g., including the passive filter 325, the TIA 330, the first op-amp based active RC filter 332, and the second op-amp based active RC filter 334) may remove the undesired up-converted portion and amplify the desired down-converted portion of the signal output by the mixer 320. In addition, the baseband filter may filter any undesired components (e.g., jammers, blockers, and/or self-interference) from the signal before providing the amplified and filtered signal to the ADC.

In some cases, the receiver hardware shown in FIG. 3 may support different gain modes, and some of the receiver hardware may be used only in high gain modes. For example, referring to FIG. 3, reference number 300A depicts a first operational state for the receiver hardware in high gain modes, where a received RF signal is amplified by the LNA 310 and down-converted by the mixer 320, and the passive filter 325, the TIA 330, and the op-amp based active RC filters 332, 334 are then used to filter and amplify the signal output by the mixer 320 (e.g., to remove an undesired up-converted portion and/or undesired down-converted components associated with jammers, blockers, and/or self-interference). In addition, reference number 300B depicts a second operational state for the receiver hardware in low gain modes, in which case a wireless receive path may bypass the LNA 310 and/or one or more amplification stages in the baseband filter. For example, in the baseband filter with the op-amp RC feedback topology shown in FIG. 3, the first op-amp based active RC filter 332 and the second op-amp based active RC filter 334 may be bypassed in one or more gain modes associated with a relatively low gain. Accordingly, all the receiver hardware is used only in one or more high gain modes, and only a subset of the receiver hardware is used in the one or more low gain modes. However, the hardware that is unused (e.g., bypassed) in the low gain modes, such as the LNA 310 and the op-amp based active RC filters 332, 334 that provide second and third order filtering, tends to occupy a large area.

As indicated above, FIG. 3 is provided as an example. Other examples may differ from what is described with regard to FIG. 3.

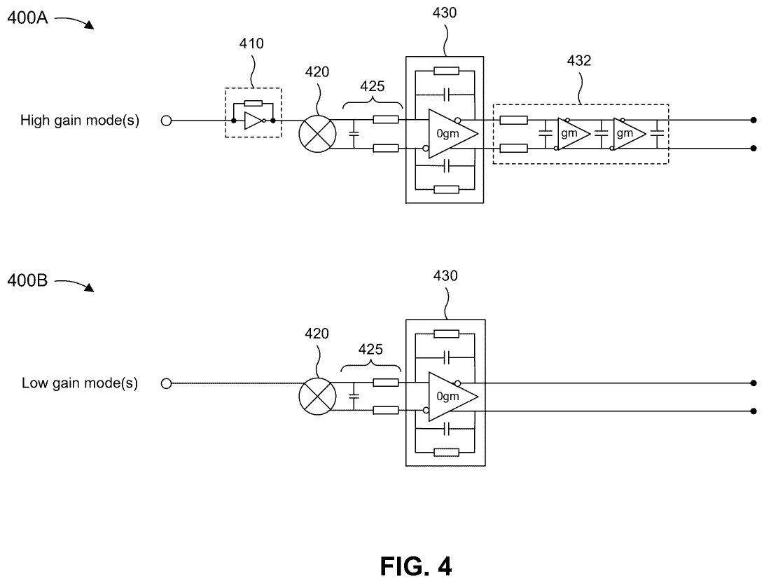

FIG. 4 is a diagram illustrating example receiver hardware that includes a tunable baseband filter, in accordance with the present disclosure. As shown in FIG. 4, the receiver hardware may include an LNA 410 that may be implemented using a self-biased inverter-based architecture to convert an input current to a voltage. In this way, by using a self-biased inverter-based architecture, the LNA 410 may occupy a smaller area than the LNA 310 shown in FIG. 3. In some aspects, the LNA 410 (which may be an example of the LNA 224, and may be implemented in the transceiver 126 or RFFE 128) may be coupled to one or more antennas (e.g., the antenna 122 or 204) and may amplify an RF signal received via the one or more antennas. As further shown in FIG. 4, the amplified signal may be provided from the LNA 410 to a mixer 420, which may down-convert the received RF signal using inputs from one or more LOs to create intermediate or baseband signals that carry encoded and modulated information. The output from the mixer 420 may then be input to a baseband filter that includes an initial filtering stage with a passive filter 425 (which may be an example of passive filter 325) and a TIA 430 (which may be an example of TIA 330) followed by a tunable transconductance-capacitance filter 432. For example, as described herein, the tunable transconductance-capacitance filter 432 may include one or more transconductance (gm) stages associated with a programmable gain. For example, the one or more gm stages may provide current-based filtering, where an output voltage from the initial filtering stage may be converted to an input current and a programmable gain may be applied to the input current according to an active gain mode. The mixer 420 may be an example of the mixer 226, the TIA stage 430 may be an example of the TIA 130, and the filter 432 may be an example of the filter 132.

In some aspects, in a receiver architecture 400A, the one or more gm stages may provide second-order and third-order filtering that may be used in one or more high gain modes, which may reduce an area associated with the baseband filter by more than 70% relative to a baseband filter that uses two-stage or three-stage op-amp-based RC filters in the one or more high gain modes (e.g., as shown in FIG. 3). For example, in a similar manner as described above with reference to FIG. 3, the mixer 420 may receive an RF signal, and an output from the mixer 420 is a down-converted RF signal that includes a desired down-converted portion and an undesired up-converted portion. Accordingly, the baseband filter (e.g., including the passive filter 425, the TIA 430, and the tunable transconductance-capacitance filter 432) may remove the undesired up-converted portion and amplify the desired down-converted portion of the signal output by the mixer 420. In addition, the baseband filter may filter any undesired components (e.g., jammers, blockers, and/or self-interference) from the signal before providing the amplified and filtered signal to an ADC (not shown in FIG. 4). Furthermore, because the one or more gm stages follow the initial filtering stage with the passive filter 425 and the TIA 430, an interface between the mixer 420 and the initial filtering stage may be unchanged (e.g., relative to the architecture shown in FIG. 3), such that the presence of the one or more gm stages is transparent in low gain modes. For example, in a receiver architecture 400B, the receiver hardware may have an operational state in low gain modes that is similar to receiver hardware that uses an op-amp based RC feedback topology. Furthermore, by using gm structures and current-based filtering, the tunable transconductance-capacitance filter 432 may support larger bandwidths that may be used for some TDD carriers. For example, baseband filters with op-amp based feedback topologies tend to support only up to 200 MHz bandwidths in sub-6 GHz bands. In contrast, by using gm structures and current-based filtering, the tunable transconductance-capacitance filter 432 may support expanded bandwidths (e.g., 1 GHz or higher) that may be used in more advanced (e.g., 6G) wireless networks. For example, as described herein, the tunable transconductance-capacitance filter 432 may provide three or more poles and one or more zeroes that can be individually tuned to optimize IP3, filter rejection, and/or droop over a band edge for different operational bandwidths. Accordingly, some aspects described herein may provide significant area reduction and performance improvements over baseband filters that use op-amp RC feedback topologies to provide second-order and third-order filtering in high gain modes. In some examples, the bandwidth of the tunable transconductance-capacitance filter (e.g., 432) may be adjustable from 1 GHz or higher down to 200 MHz, or 20 MHz or 10 MHz in other examples, e.g., such that both advanced (e.g., 6G) networks and traditional networks may be supported.

As can be seen in FIG. 4, the baseband filter (which may be an example of the BBF 228) may include only one TIA (e.g., TIA 430), may include only one TIA for the corresponding mixer (e.g., TIA 430 for the mixer 420), and/or may not include any TIAs after an initial TIA (e.g., TIA 430). In some other aspects, the TIA 430 is omitted such that the baseband filter does not include any TIAs and instead includes only the filter 432 (e.g., including one or more gm or gmC stages).

As indicated above, FIG. 4 is provided as an example. Other examples may differ from what is described with regard to FIG. 4.

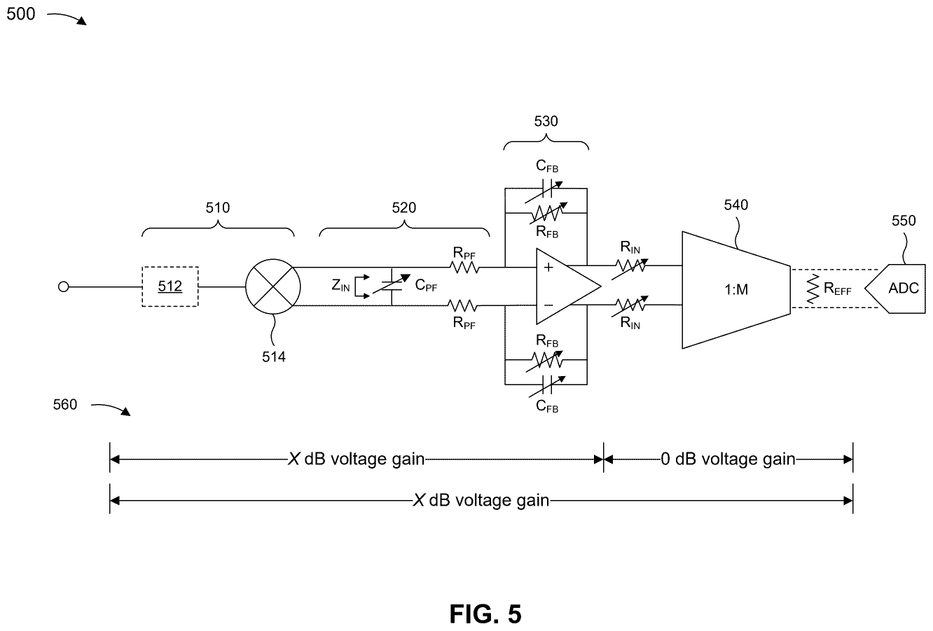

FIG. 5 is a diagram illustrating example receiver hardware 500 that includes a tunable transconductance-capacitance filter 540, in accordance with the present disclosure. For example, as shown in FIG. 5, the receiver hardware includes an RFFE 510, where the RFFE 510 may include an LNA 512 (which may be an example of the LNA 410) coupled to one or more antennas (e.g., the antenna 122 or 204), and a mixer 514 (which may be an example of the mixer 420) that down-converts an RF signal that is received via the one or more antennas and amplified by the LNA 512 according to inputs from one or more LOs to create an intermediate signal. As further shown in FIG. 5, the receiver hardware includes a passive filter 520 (which may be an example of the passive filter 325 or the passive filter 425), which includes a variable capacitor CPF coupled to a pair of resistors RPF, wherein an input impedance across the capacitor CPF is denoted ZIN. As further shown in FIG. 5, an output from the passive filter 520 is provided to a TIA 530 (which may be an example of the TIA 430), which includes a first variable feedback resistor RFB and a first variable feedback capacitor CFB coupled between a positive input node and a positive output node, and a second variable feedback resistor RFB and a second variable feedback capacitor CFB coupled between a negative input node and a negative output node.

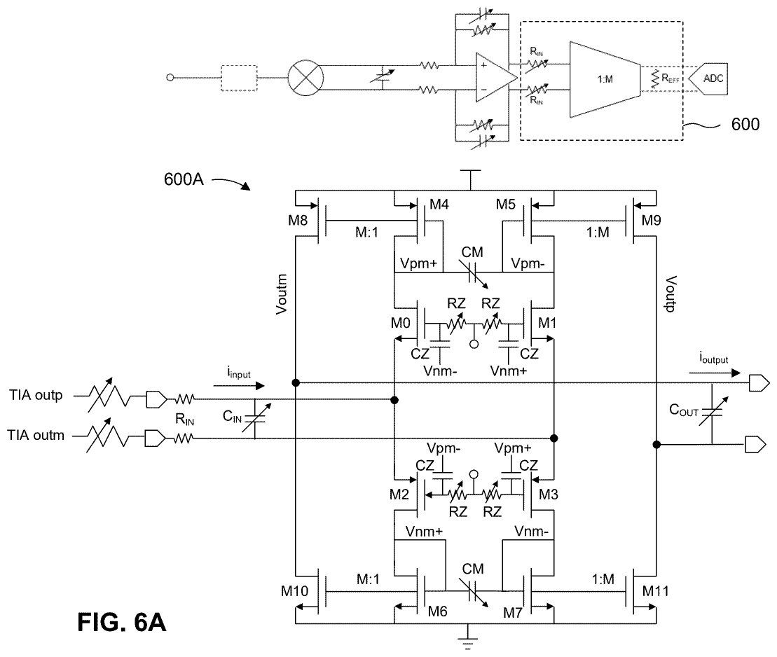

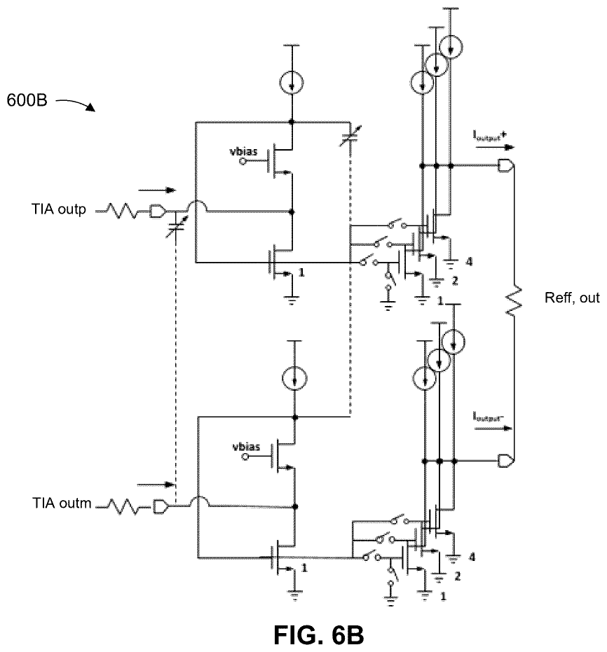

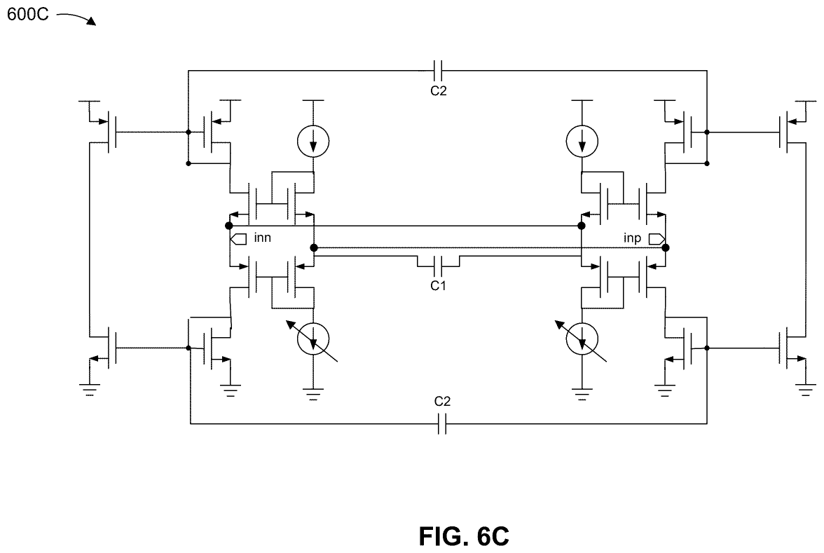

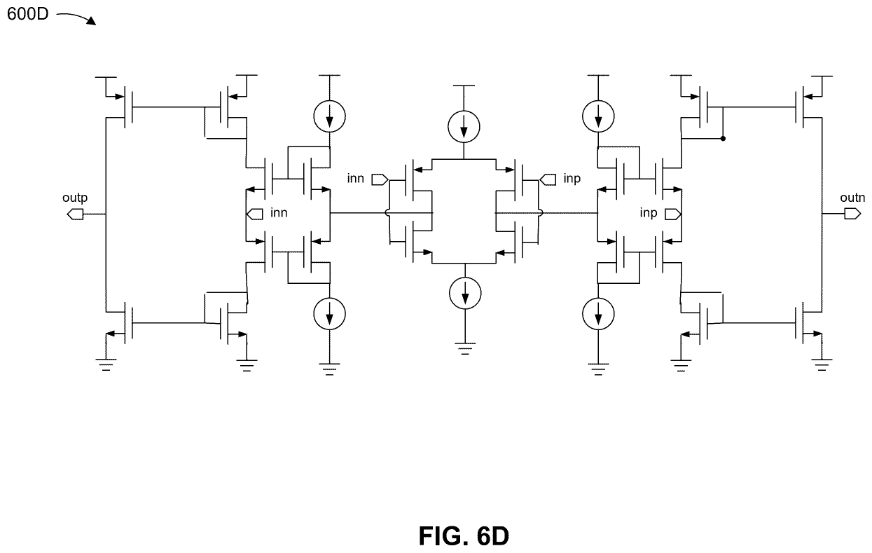

In some aspects, an output from the TIA 530 is in a voltage domain, such that the TIA 530 generates an output voltage that is provided to the transconductance-capacitance filter 540 as an input voltage. The input voltage is converted to an input current using a pair of resistors R_{IN} that are respectively coupled to the positive and negative output nodes from the TIA 530. The transconductance-capacitance filter 540 then applies a gain to the input current, where the gain may be represented as 1:M, where M is a ratio of the output current to the input current. After the gain is applied to the input current, the signal is provided to an ADC 550 (which may be an example of the ADC 134) as a voltage, according to an effective resistance R_{EFF} associated with the ADC 550. Accordingly, as described herein, the wireless signal received via the one or more antennas is filtered at the transconductance-capacitance filter 540, which applies a 1:M gain to the input current based on an active gain mode. For example, as described in further detail below with reference to FIGS. 6A-6D, the transconductance-capacitance filter 540 may provide three poles (or fewer in some configurations) with similar current consumption, where one or more resistances, capacitances, biases, and/or other parameters may be programmed to configure the gain (e.g., the gain ratio, M, may have a value equal to 1 to provide no voltage gain in one or more low gain modes, or may have a value greater than 1 to provide some voltage gain in one or more gain modes). For example, reference number 560 depicts an example where the transconductance-capacitance filter 540 provides a 1:1 gain, whereby an RF signal received via one or more antennas experiences an X decibel (dB) voltage gain across the RFFE 510, the passive filter 520, and the TIA 530, and 0 dB voltage gain across the filter 540. In this way, when the filter 540 is used in a wireless receiver with processing paths for multiple carriers that may be associated with different frequencies, the gain provided by the filter 540 and/or other parameters associated with the filter 540 may be programmable based on the frequency or power associated with the received signal. Elements disposed between the TIA 530 and ADC 550 may be an example of the filter 132).

As indicated above, FIG. 5 is provided as an example. Other examples may differ from what is described with regard to FIG. 5.

FIGS. 6A-6D are diagrams illustrating examples of a tunable transconductance-capacitance filter 600 that may be used in a wireless receiver, in accordance with the present disclosure. In some aspects, the tunable transconductance-capacitance filter 600 is an example implementation for the tunable transconductance-capacitance filter 540 shown in FIG. 5, and may be implemented in combination with the receiver hardware shown in FIG. 5 and/or any other suitable wireless receiver hardware. As shown in FIG. 6A, in a first example, the tunable transconductance-capacitance filter 600A may be implemented as a circuit that includes an input stage, a current mirror stage, and an output stage. In some aspects, the input stage may be a transconductance (gm) stage and the output stage may be a capacitance (c) stage, such that the filter 600A in FIG. 6A may be referred to as a gm-cm-c filter 600A. In some aspects, the tunable transconductance-capacitance filter 600A implements poles associated with one or more transconductances, a current mirror, and a capacitance, and therefore may be referred to as a gm-cm-c filter in some examples.

As shown in FIG. 6A, the input stage includes an input capacitor C_{IN} with a variable (e.g., programmable) capacitance, a first input resistor R_{IN} coupled to a positive TIA output (shown as TIA outp), and a second input resistor R_{IN} coupled to a negative TIA output (shown as TIA outm). In FIG. 6A, the positive TIA output and the negative TIA output are shown as coupled to variable resistors, which are shown to illustrate the resistance associated with the capacitor and resistor across the input and output from the TIA (e.g., shown as CFB and RFB in FIG. 5). In addition, the pentagonal elements coupled to the input resistors R_{IN} represent inputs to the filter 600 (e.g., an interface between the filter 600 and the TIA), and the pentagonal elements coupled to the output capacitor Cour represent outputs from the filter 600 (e.g., an interface between the filter 600 and the ADC). In some aspects, in the example filter 600A shown in FIG. 6A, the input capacitor and the input resistors are associated with a first pole, and provide first-order filtering for the signal output by the TIA. For example, the first pole has a value

$$\frac{{gm}_{in}}{2 {C}_{in}} ,$$

where gmᵢₙ is a transconductance of the input stage and Cᵢₙ is a capacitance of the input capacitor. The input stage is configured to receive an input voltage from the TIA, and to convert the input voltage to an input current iᵢₙₚᵤₜ.

As further shown in FIG. 6A, the current mirror stage includes a transistor network and one or more differential capacitors that may provide second-order filtering for the signal output from the TIA. For example, the transistor network and the one or more differential capacitors are configured to receive the input current and apply a gain to the input current to generate an output current iₒᵤₜₚᵤₜ. For example, as shown in FIG. 6A, the transistor network includes common gate transistors M0 and M2 each with a source coupled to the first input resistor connected to the positive TIA output and common gate transistors M1 and M3 each with a source coupled to the second input resistor connected to the negative TIA output. The transistors M0-M3 may receive the input current with

$$\frac{1}{gm}$$

as the input impedance, which provides a low impedance for the voltage-to-current conversion at the input stage, which is primarily based on the resistance of the input resistors to satisfy a linearity requirement. As further shown in FIG. 6A, the transistor network in the current mirror stage includes transistors M4 and M8 coupled to transistor M0 as a current mirror, transistors M5 and M9 coupled to transistor M1 as a current mirror, transistors M6 and M10 coupled to transistor M2 as a current mirror, and transistors M7 and M11 coupled to transistor M3 as a current mirror, to provide the 1:M gain ratio for the input current. For example, the gain of the circuit may be defined as

$$\frac{{R}_{ADC}}{2 {R}_{in} \times M} ,$$

where R_{ADC} IS a resistance equivalent to a resistance of the ADC coupled to the output stage, Rᵢₙ is a resistance of each input resistor, and M is the gain ratio. In some aspects, the values of Rᵢₙ and M may be programmed to adjust the gain of the transconductance-capacitance filter 600A (e.g., depending on a gain mode in which the filter 600A is operating). As further shown, the current mirror stage includes differential capacitors C_{M} that are associated with a second pole. For example, the second pole has a value

$$\frac{{gm}_{Mirror}}{2 {C}_{M}} ,$$

where gm_{Mirror} is a transconductance of the current mirror stage and C_{M} is a capacitance of each capacitor C_{M}, such that the capacitance of the capacitors C_{M} can be programmed to tune the second pole.

As further shown in FIG. 6A, the output stage includes an output capacitor C_{OUT} with a variable (e.g., programmable) capacitance to maintain the output current iₒᵤₜₚᵤₜ and provide the output current to an ADC. As shown, the output capacitor has a first terminal coupled to a positive output voltage (shown as Voutp) and a second terminal coupled to a negative output voltage (shown as Voutm). In some aspects, the output capacitor is associated with a third pole, and provides third-order filtering for the signal output by the TIA. For example, the third pole has a value

$$\frac{{R}_{ADC}}{2 {C}_{out}} ,$$

where R_{ADC} is a resistance equivalent to a resistance of the ADC coupled to the output stage and Cₒᵤₜ is a capacitance of the output capacitor. The input stage is configured to receive an input voltage from the TIA, and to convert the input voltage to an input current iᵢₙₚᵤₜ.

As further shown in FIG. 6A, the current mirror stage may include a droop compensation circuit, where the droop compensation circuit includes one or more RC circuits to compensate for a droop at a band edge. For example, the droop compensation circuit may include a first pair of resistors R_{Z} and a first pair of capacitors C_{Z} coupled between transistors M0 and M1, and a second pair of resistors R_{Z} and a second pair of capacitors C_{Z} coupled between transistors M2 and M3. As shown, a first input (e.g., a supply voltage or bias current) is coupled between the first pair of resistors R_{Z}, and a second input is coupled between the second pair of resistors R_{Z}. In addition, the first pair of capacitors C_{Z} coupled between transistors M0 and M1 are respectively coupled to nodes Vnm− and Vnm+ that are respectively coupled to drains of transistors M3 and M2, and the second pair of capacitors C_{Z} coupled between transistors M2 and M3 are respectively coupled to nodes Vpm− and Vpm+ that are respectively coupled to drains of transistors M1 and M0. In some aspects, the droop compensation circuit may provide a biquad filter function, with a zero at

$$\frac{1}{Rz \times Cz} ,$$

where R_{Z} is a resistance of each resistor R_{Z} and C_{Z} is a capacitance of each capacitor C_{Z}. Accordingly, the resistances of the resistors R_{Z} and the capacitances of the capacitors C_{Z} may be programmed to tune the zero and thereby optimize the droop compensation (e.g., providing more rejection and less droop) at the band edge. In other aspects, R_{Z} and C_{Z} may be omitted.

In some aspects, as described herein, various parameters associated with the transconductance-capacitance filter 600A may be programmed to tune the operation of the transconductance-capacitance filter 600A (e.g., depending on a gain mode and/or a frequency of a signal to be filtered). For example, the Rᵢₙ value and M ratio may be programmed to tune the gain. In another example, a programmable bias current I_{bias} may be applied to the transconductance-capacitance filter 600A to tune the transconductance of the transconductance-capacitance filter 600A (e.g., direct current bias voltages for transistors M4/M5 and M6/M7 may be generated in a bias circuit to set a desired I_{bias} for transistors M4/M5 and M6/M7). In another example, the Cᵢₙ, C_{M}, and Cₒᵤₜ values may be programmed to individually and respectively tune the first pole, the second pole, and the third pole. For example, in some aspects, the Cᵢₙ value may be increased to improve an IP3 at a band edge and to increase rejection at the band edge. However, increasing the Cᵢₙ value may result in an increased droop at the band edge, which may be compensated by programming the R_{Z} and C_{Z} values to tune the zero, as described herein. In some aspects, increasing the C_{M} value may degrade the IP3 performance and increase droop at the band edge, but may increase rejection at the band edge. Accordingly, a combination of the first pole associated with the input stage and the second pole associated with the current mirror stage may provide a flat IP3 over the band edge, and any droop increase may be compensated by appropriately programming the R_{Z} and C_{Z} values. For example, increasing the C_{M} value and programming the R_{Z} and C_{Z} values can generate a biquad pole that reduces in-band droop while maintaining out-of-band rejection. For example, the R_{Z} and C_{Z} values may be programmed to place the zero close to the band edge in order to reduce the droop associated with the transconductance-capacitance filter 600A. In some aspects, a relatively higher R_{Z} value and a relatively lower C_{Z} value may achieve the desired biquad effect, whereby the area occupied by the capacitors C_{Z} may be reduced significantly by using resistors with higher R_{Z} values. Furthermore, in some aspects, increasing the Cₒᵤₜ value may improve the IP3 performance at the band edge, and a noise figure degrades only with noise associated with the ADC. Accordingly, in cases where only one pole is programmed, the Cₒᵤₜ value (associated with the third pole) may be programmed to optimize performance for different operational bandwidths.

Additionally, or alternatively, FIGS. 6B-6D illustrate other possible filters 600B-600D that may be used to implement the tunable transconductance-capacitance filter 540 shown in FIG. 5. For example, FIG. 6B illustrates an example filter 600B that may be implemented using a low-voltage super common-gate configuration, where the positive TIA output is coupled to a first stage with a node between a first transistor and a second transistor, where the first transistor is coupled to a current source and to a bias voltage, and the second transistor is coupled to the current source and to ground. Similarly, the negative TIA output is coupled to a node in the first stage between a first transistor and a second transistor, where the first transistor is coupled to a current source and to a bias voltage, and the second transistor is coupled to the current source and to ground. In a second stage, various current sources are switchably coupled between the first stage and respective output nodes. In the design shown in FIG. 6B, a ratio of the input current to the output current may be given by:

$$\frac{{i}_{output}}{{i}_{input}} = \frac{M}{1 + s \frac{{C}_{2}}{{g}_{m 1}} + {s}^{2} \frac{{C}_{1} {C}_{2}}{{g}_{m 1} {g}_{m 2}}}$$

Additionally, or alternatively, FIG. 6C illustrates an example filter 600C that may be implemented using a level-shifted differential boosted complementary CMC configuration, where an input resistance is given by:

$${Z}_{in} = \frac{1}{2 ( gmn + gmp )}$$

and FIG. 6D illustrates an example filter 600D that may also be implemented using a level-shifted differential boosted complementary CMC configuration similar to filter 600C, except omitting capacitors C1 and C2 relative to filter 600C.

In some configurations, the number of poles provided by the filter 600 may depend on which configuration (e.g., 600A-600D) is implemented. While FIG. 6A illustrates a single filter 600, two (e.g., as illustrated in FIG. 4) or more filters may be coupled in series. In some examples, additional poles may be realized by coupling such filters in series. The series filters may all have the same configuration (e.g., all filters may be configured as illustrated in FIG. 6A), or the series filters may be a mix of different configurations (e.g., selected from the filters 600A-600D or another gm or gm-cm-c filter).

As indicated above, FIGS. 6A-6D are provided as examples. Other examples may differ from what is described with regard to FIGS. 6A-6D.

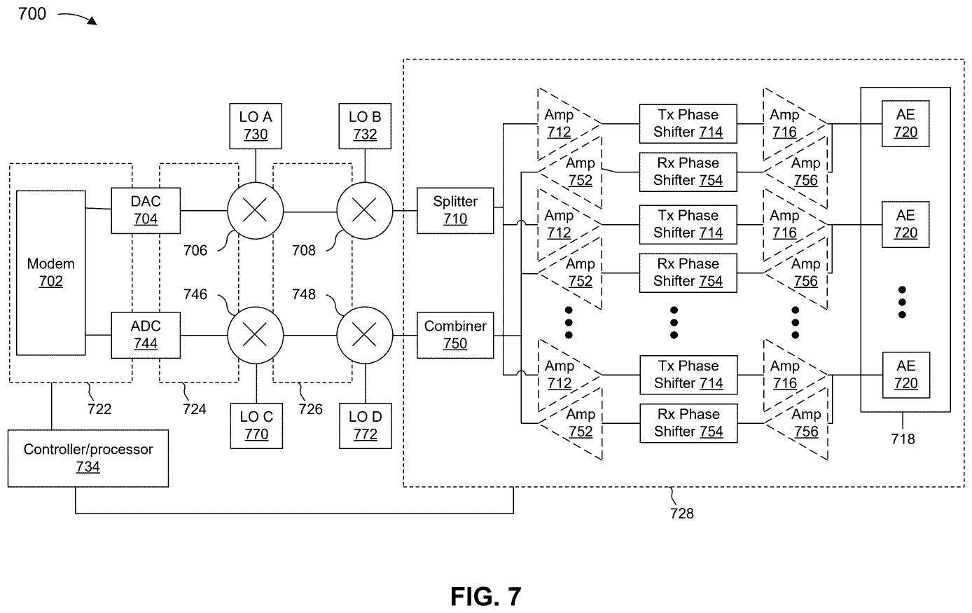

FIG. 7 is a diagram illustrating an example beamforming architecture 700, in accordance with the present disclosure. The beamforming architecture 700 may include, may implement, and/or may be implemented in the electronic device 102 shown in FIG. 1, the transceiver 200 shown in FIG. 2, the receiver architecture 400A, 400B shown in FIG. 4, the receiver hardware 500 shown in FIG. 5, and/or the tunable transconductance-capacitance filter 600A-600D shown in any of FIGS. 6A-6D.

As described herein, FIG. 7 illustrates example hardware components of a wireless communication device in accordance with certain aspects of the disclosure. The illustrated components may include those that may be used for antenna element selection and/or for beamforming for transmission of wireless signals. There are numerous architectures for antenna element selection and implementing phase shifting, only one example of which is illustrated in FIG. 7. The beamforming architecture 700 may include a modem (modulator/demodulator) 702, a DAC 704, a first mixer 706, a second mixer 708, and a splitter 710. The beamforming architecture 700 may also include multiple first amplifiers 712, multiple phase shifters 714, multiple second amplifiers 716, and an antenna array 718 that includes multiple antenna elements 720.

Transmission lines or other waveguides, wires, and/or traces are shown to connect components to illustrate how signals transmitted travel between components. Reference numbers 722, 724, 726, and 728 indicate regions in the beamforming architecture 700 in which different types of signals travel or are processed. Specifically, reference number 722 indicates a region in which digital baseband signals travel or are processed, reference number 724 indicates a region in which analog baseband signals travel or are processed, reference number 726 indicates a region in which analog IF signals travel or are processed, and reference number 728 indicates a region in which analog RF signals travel or are processed. The beamforming architecture 700 also includes an LO A 730, an LO B 732, and a controller/processor 734.

Each of the antenna elements 720 may include one or more sub-elements for radiating or receiving RF signals. For example, a single antenna element 720 may be configured to operate in in multiple polarizations and/or include a first sub-element cross-polarized with a second sub-element that can be used to independently transmit cross-polarized signals. The antenna elements 720 may include patch antennas, dipole antennas, or other types of antennas arranged in a linear pattern, a two dimensional pattern, or another pattern. A spacing between antenna elements 720 may be such that signals with a desired wavelength transmitted separately by the antenna elements 720 may interact or interfere (e.g., to form a desired beam). For example, given an expected range of wavelengths or frequencies, the spacing may provide a quarter wavelength, half wavelength, or other fraction of a wavelength of spacing between neighboring antenna elements 720 to allow for interaction or interference of signals transmitted by the separate antenna elements 720 within that expected range.

The modem 702 may process and generate digital baseband signals and may also control operation of the DAC 704, the first and second mixers 706 and 708, the splitter 710, the first amplifiers 712, the phase shifters 714, and/or the second amplifiers 716 to transmit signals via one or more or all of the antenna elements 720. The modem 702 may process signals and control operation in accordance with a communication standard such as a wireless communication standard. The DAC 704 may convert digital baseband signals received from the modem 702 (and that are to be transmitted) into analog baseband signals. The first mixer 706 may up-convert analog baseband signals to analog IF signals within an IF using an LO A 730. For example, the first mixer 706 may mix the signals with an oscillating signal generated by the LO A 730 to shift the baseband analog signals to the IF. In some aspects, some processing or filtering (not shown) may take place at the IF. The second mixer 708 may up-convert the analog IF signals to analog RF signals using the LO B 732. Similar to the first mixer, the second mixer 708 may mix the signals with an oscillating signal generated by the LO B 732 to shift the IF analog signals to the RF or the frequency at which signals will be transmitted or received. The modem 702 and/or the controller/processor 734 may adjust the frequency of the LO A 730 and/or the LO B 732 so that a desired IF and/or RF frequency is produced and used to facilitate processing and transmission of a signal within a desired bandwidth.

In the illustrated beamforming architecture 700, signals up-converted by the second mixer 708 are split or duplicated into multiple signals by the splitter 710. The splitter 710 in the beamforming architecture 700 may split the RF signal into multiple identical or nearly identical RF signals. In other examples, the split may take place with any type of signal, including with baseband digital, baseband analog, or IF analog signals. Each signal may correspond to an antenna element 720, and the signal travels through and is processed by the amplifiers 712, 716, the phase shifters 714, and/or other elements corresponding to the respective antenna element 720 to be provided to and transmitted by the corresponding antenna element 720 of the antenna array 718. For example, the splitter 710 may be an active splitter connected to a power supply to provide some gain so that RF signals exiting the splitter 710 are at a power level equal to or greater than the signal entering the splitter 710. In another example, the splitter 710 is a passive splitter that is not connected to power supply and the RF signals exiting the splitter 710 may be at a lower power than the RF signal entering the splitter 710.

After being split by the splitter 710, the resulting RF signals may enter an amplifier, such as a first amplifier 712, or a phase shifter 714 corresponding to an antenna element 720. In other examples, LO path phase shifting is implemented instead of the illustrated signal path phase shifting. The first and second amplifiers 712, 716 are illustrated with dashed lines because one or both might not be necessary in some aspects. In some aspects, both the first amplifier 712 and second amplifier 716 are present. In some aspects, neither the first amplifier 712 nor the second amplifier 716 is present. In some aspects, one of the two amplifiers 712, 716 is present but not the other. By way of example, if the splitter 710 is an active splitter, the first amplifier 712 may not be used. By way of further example, if the phase shifter 714 is an active phase shifter that can provide a gain, the second amplifier 716 might not be used.

The amplifiers 712, 716 may provide a desired level of positive or negative gain. A positive gain (positive dB) may be used to increase an amplitude of a signal for radiation by a specific antenna element 720. A negative gain (negative dB) may be used to decrease an amplitude and/or suppress radiation of the signal by a specific antenna element. Each of the amplifiers 712, 716 may be controlled independently (e.g., by the modem 702 or the controller/processor 734) to provide independent control of the gain for each antenna element 720. For example, the modem 702 and/or the controller/processor 734 may have at least one control line connected to each of the splitter 710, first amplifiers 712, phase shifters 714, and/or second amplifiers 716 that may be used to configure a gain to provide a desired amount of gain for each component and thus each antenna element 720.

The phase shifter 714 may provide a configurable phase shift or phase offset to a corresponding RF signal to be transmitted. The phase shifter 714 may be a passive phase shifter not directly connected to a power supply. Passive phase shifters might introduce some insertion loss. The second amplifier 716 may boost the signal to compensate for the insertion loss. The phase shifter 714 may be an active phase shifter connected to a power supply such that the active phase shifter provides some amount of gain or prevents insertion loss. The settings of each phase shifter 714 are independent, meaning that each can be independently set to provide a desired amount of phase shift or the same amount of phase shift or some other configuration. The modem 702 and/or the controller/processor 734 may have at least one control line connected to each of the phase shifters 714 and which may be used to configure the phase shifters 714 to provide a desired amount of phase shift or phase offset between antenna elements 720.

In the illustrated beamforming architecture 700, RF signals received by the antenna elements 720 are provided to one or more first amplifiers 756 to boost the signal strength. The first amplifiers 756 may be connected to the same antenna arrays 718 (e.g., for TDD operations). The first amplifiers 756 may be connected to different antenna arrays 718. The boosted RF signal is input into one or more phase shifters 754 to provide a configurable phase shift or phase offset for the corresponding received RF signal to enable reception via one or more Rx beams. The phase shifter 754 may be an active phase shifter or a passive phase shifter. The settings of the phase shifters 754 are independent, meaning that each can be independently set to provide a desired amount of phase shift or the same amount of phase shift or some other configuration. The modem 702 and/or the controller/processor 734 may have at least one control line connected to each of the phase shifters 754 and which may be used to configure the phase shifters 754 to provide a desired amount of phase shift or phase offset between antenna elements 720 to enable reception via one or more Rx beams.

The outputs of the phase shifters 754 may be input to one or more second amplifiers 752 for signal amplification of the phase shifted received RF signals. The second amplifiers 752 may be individually configured to provide a configured gain. The second amplifiers 752 may be individually configured to provide an amount of gain to ensure that the signals input to combiner 750 have the same magnitude. The amplifiers 752 and/or 756 are illustrated in dashed lines because they might not be necessary in some aspects. In some aspects, both the amplifier 752 and the amplifier 756 are present. In another aspect, neither the amplifier 752 nor the amplifier 756 are present. In other aspects, one of the amplifiers 752, 756 is present but not the other.

In the beamforming architecture 700, signals output by the phase shifters 754 (via the amplifiers 752 when present) are combined in combiner 750. The combiner 750 may combine the RF signals into a signal. The combiner 750 may be a passive combiner (e.g., not connected to a power source), which may result in some insertion loss. The combiner 750 may be an active combiner (e.g., connected to a power source), which may result in some signal gain. When combiner 750 is an active combiner, it may provide a different (e.g., configurable) amount of gain for each input signal so that the input signals have the same magnitude when they are combined. When combiner 750 is an active combiner, the combiner 750 may not need the second amplifier 752 because the active combiner may provide the signal amplification.

The output of the combiner 750 is input into mixers 748 and 746. Mixers 748 and 746 generally down-convert the received RF signal using inputs from LOs 772 and 770, respectively, to create intermediate or baseband signals that carry the encoded and modulated information. The output of the mixers 748 and 746 are input into an ADC 744 for conversion to digital signals. In some aspects, the filters 600A-600D shown in any of FIGS. 6A-6D may be implemented as baseband filters between the output of the mixers 748 and 746 and the ADC 744. The digital signals output from ADC 744 are input to modem 702 for baseband processing, such as decoding, de-interleaving, or similar operations.

The beamforming architecture 700 is given by way of example only to illustrate an architecture for transmitting and/or receiving signals. In some cases, the beamforming architecture 700 and/or each portion of the beamforming architecture 700 may be repeated multiple times within an architecture to accommodate or provide an arbitrary number of RF chains, antenna elements, and/or antenna panels. Furthermore, numerous alternate architectures are possible and contemplated. For example, although only a single antenna array 718 is shown, two, three, or more antenna arrays may be included, each with one or more of their own corresponding amplifiers, phase shifters, splitters, mixers, DACs, ADCs, and/or modems. For example, a single UE may include two, four, or more antenna arrays for transmitting or receiving signals at different physical locations on the UE or in different directions.

Furthermore, mixers, splitters, amplifiers, phase shifters and other components may be located in different signal type areas (e.g., represented by different ones of the reference numbers 722, 724, 726, 728) in different implemented architectures. For example, a split of the signal to be transmitted into multiple signals may take place at the analog RF, analog IF, analog baseband, or digital baseband frequencies in different examples. Similarly, amplification and/or phase shifts may also take place at different frequencies. For example, in some aspects, one or more of the splitter 710, amplifiers 712, 716, or phase shifters 714 may be located between the DAC 704 and the first mixer 706 or between the first mixer 706 and the second mixer 708. In one example, the functions of one or more of the components may be combined into one component. For example, the phase shifters 714 may perform amplification to include or replace the first and/or or second amplifiers 712, 716. By way of another example, a phase shift may be implemented by the second mixer 708 to obviate the need for a separate phase shifter 714. This technique is sometimes called LO phase shifting. In some aspects of this configuration, there may be multiple IF to RF mixers (e.g., for each antenna element chain) within the second mixer 708, and the LO B 732 may supply different local oscillator signals (with different phase offsets) to each IF to RF mixer.

The modem 702 and/or the controller/processor 734 may control one or more of the other components 704 through 772 to select one or more antenna elements 720 and/or to form beams for transmission of one or more signals. For example, the antenna elements 720 may be individually selected or deselected for transmission of a signal (or signals) by controlling an amplitude of one or more corresponding amplifiers, such as the first amplifiers 712 and/or the second amplifiers 716. Beamforming includes generation of a beam using multiple signals on different antenna elements, where one or more or all of the multiple signals are shifted in phase relative to each other. The formed beam may carry physical or higher layer reference signals or information. As each signal of the multiple signals is radiated from a respective antenna element 720, the radiated signals interact, interfere (constructive and destructive interference), and amplify each other to form a resulting beam. The shape (such as the amplitude, width, and/or presence of side lobes) and the direction (such as an angle of the beam relative to a surface of the antenna array 718) can be dynamically controlled by modifying the phase shifts or phase offsets imparted by the phase shifters 714 and amplitudes imparted by the amplifiers 712, 716 of the multiple signals relative to each other. The controller/processor 734 may be located partially or fully within one or more other components of the beamforming architecture 700. For example, the controller/processor 734 may be located within the modem 702 in some aspects.

As indicated above, FIG. 7 is provided as an example. Other examples may differ from what is described with regard to FIG. 7.

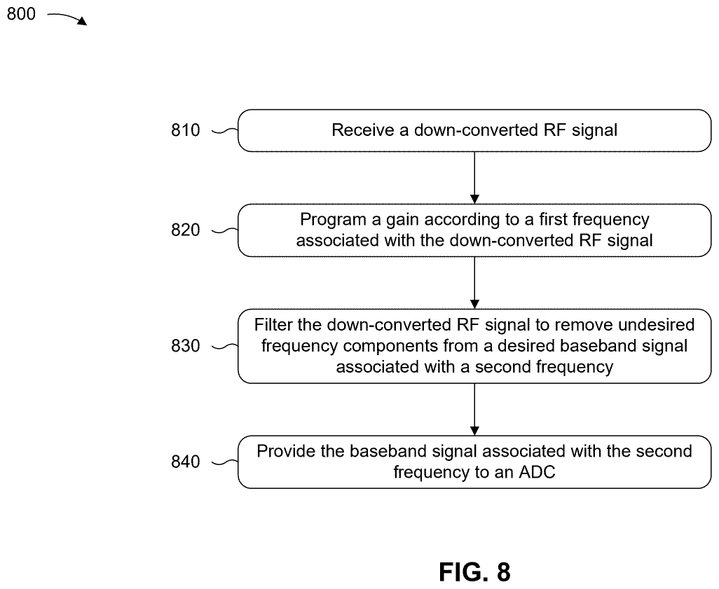

FIG. 8 is a flowchart illustrating an example method 800 for filtering a signal in a wireless receive path, in accordance with the present disclosure. In some aspects, one or more process blocks of FIG. 8 are performed by a circuit (e.g., filter 540 or transconductance-capacitance filter 600A-600D shown in any of FIGS. 6A-6D). In some aspects, one or more process blocks of FIG. 8 are performed by another device or a group of devices separate from or including the circuit, such as RFFE 510, passive filter 520, TIA 530, and/or ADC 550, among other examples.

As shown in FIG. 8, method 800 may include receiving a down-converted RF signal (block 810). For example, the circuit may receive a down-converted RF signal, as described above.

As further shown in FIG. 8, method 800 may include programming a gain associated according to a first frequency associated with the down-converted RF signal (block 820). For example, the circuit may program a gain according to a first frequency associated with the down-converted RF signal, as described above.

As further shown in FIG. 8, method 800 may include filtering the down-converted RF signal to remove undesired frequency components from a desired baseband signal associated with a second frequency (block 830). For example, the circuit may filter the down-converted RF signal to remove undesired frequency components from a desired baseband signal associated with a second frequency, as described above.

As further shown in FIG. 8, method 800 may include providing the desired baseband signal associated with the second frequency to an ADC (block 840). For example, the circuit may provide the desired baseband signal associated with the second frequency to an ADC, as described above.

Method 800 may include additional aspects, such as any single aspect or any combination of aspects described below and/or in connection with one or more other processes described elsewhere herein.

In a first aspect, filtering the RF signal includes converting, at a transconductance (gm) stage of the circuit, an input voltage associated with the down-converted RF signal to an input current; applying, at a current mirror (cm) stage of the circuit, the programmed gain to the input current to generate an output current; and providing, at a capacitance (c) stage of the circuit, capacitance to maintain the output current for the desired baseband signal.

In a second aspect, alone or in combination with the first aspect, programming the gain associated with the circuit includes programming a resistance of the gm stage according to the first frequency associated with the down-converted RF signal, and programming a gain mode ratio associated with the cm stage according to the first frequency associated with the down-converted RF signal.

In a third aspect, alone or in combination with one or more of the first and second aspects, method 800 includes programming a capacitance of the gm stage to tune a first pole associated with the gm stage according to the first frequency associated with the down-converted RF signal, programming a capacitance of the cm stage to tune a second pole associated with the gm stage according to the first frequency associated with the down-converted RF signal, and programming a capacitance of the c stage to tune a third pole associated with the c stage according to the first frequency associated with the down-converted RF signal.

In some aspects, the resistance of the gm stage, the gain mode ratio associated with the cm stage, the capacitance of the gm stage, the capacitance of the cm stage, and the capacitance of the c stage, and/or any other suitable programmable aspect described herein may be programmed by the communication processor 124 of FIG. 1, the modem 702 of FIG. 7, the controller/processor 734 of FIG. 7, or the like.

In a fourth aspect, alone or in combination with one or more of the first through third aspects, method 800 includes compensating, by one or more RC circuits included in the cm stage, droop in an output voltage associated with the cm stage.

Although FIG. 8 shows example blocks of method 800, in some aspects, method 800 includes additional blocks, fewer blocks, different blocks, or differently arranged blocks than those depicted in FIG. 8. Additionally, or alternatively, two or more of the blocks of method 800 may be performed in parallel.

The following provides an overview of some Aspects of the present disclosure:

Aspect 1: A baseband filter, comprising: a transimpedance amplifier to receive a down-converted radio frequency (RF) signal and to filter and amplify the down-converted RF signal; a filter configured to receive the amplified down-converted RF signal and to filter the amplified down-converted RF signal to remove undesired frequency components from a desired baseband signal, wherein the filter comprises: a first stage, associated with a first pole, to convert an input voltage associated with the amplified down-converted RF signal to an input current; a second stage, associated with a second pole, to apply a gain to the input current to generate an output current; and a third stage, associated with a third pole, to maintain the output current and provide the desired baseband signal to an analog-to-digital converter (ADC); and a programming interface to receive one or more instructions to tune one or more of the first pole, the second pole, the third pole, or the gain applied to the input current based on a frequency associated with the down-converted RF signal.

Aspect 2: The baseband filter of Aspect 1, wherein the first pole is based on a transconductance and a capacitance of the first stage.

Aspect 3: The baseband filter of any of Aspects 1-2, wherein the second pole is based on a transconductance and a capacitance of the second stage.

Aspect 4: The baseband filter of any of Aspects 1-3, wherein the third pole is based on a resistance of the ADC and a capacitance of the third stage.

Aspect 5: The baseband filter of any of Aspects 1-4, wherein the one or more instructions configure a capacitance of the first stage to tune the first pole, a capacitance of the second stage to tune the second pole, or a capacitance of the third stage to tune the third pole.

Aspect 6: The baseband filter of any of Aspects 1-5, wherein the one or more instructions configure a one or more of a resistance or a capacitance of the second stage to tune a zero that compensates for a droop associated with the desired baseband signal.

Aspect 7: The baseband filter of any of Aspects 1-6, wherein the one or more instructions configure a bias current applied to the second stage to tune a transconductance of the second stage.

Aspect 8: The baseband filter of any of Aspects 1-7, wherein the one or more instructions configure a resistance of the first stage to tune the gain applied to the input current.

Aspect 9: A filter, comprising: an input stage comprising a resistor-capacitor (RC) circuit configured to receive an input voltage and convert the input voltage to an input current; a current mirror stage comprising a transistor network and one or more differential capacitors configured to receive the input current and apply a gain to the input current to generate an output current; and an output stage comprising an output capacitor coupled between an output from the current mirror stage and an input to an analog-to-digital converter (ADC) to maintain the output current.

Aspect 10: The filter of Aspect 9, wherein the filter is associated with a first pole based on a transconductance and a capacitance of the input stage, a second pole based on a transconductance and a capacitance of the current mirror stage, and a third pole based on a resistance of the ADC and a capacitance of the output capacitor.

Aspect 11: The filter of Aspect 10, wherein the capacitance of the input stage, the capacitance of the current mirror stage, and the capacitance of the output capacitor are programmable to respectively tune the first pole, the second pole, and the third pole.

Aspect 12: The filter of Aspect 10, wherein the transconductance of the current mirror stage is based on a programmable bias current applied to the current mirror stage.

Aspect 13: The filter of any of Aspects 9-12, wherein the filter is associated with a gain based on a resistance of the ADC, a resistance of the input stage, and a gain mode ratio.

Aspect 14: The filter of Aspect 13, wherein the resistance of the input stage and the gain mode ratio are programmable to tune the gain.

Aspect 15: The filter of any of Aspects 9-14, wherein the current mirror stage further comprises one or more RC circuits configured to compensate droop in an output voltage associated with the current mirror stage.

Aspect 16: The filter of Aspect 15, wherein the filter is associated with a zero based on a resistance and a capacitance of the one or more RC circuits.

Aspect 17: A method, comprising: receiving a down-converted radio frequency (RF) signal at a circuit; programming a gain associated with the circuit according to a first frequency associated with the down-converted RF signal; and filtering, by the circuit, the down-converted RF signal to remove undesired frequency components from a desired baseband signal associated with a second frequency, wherein the filtering the down-converted RF signal includes: converting, at a transconductance (gm) stage of the circuit, an input voltage associated with the down-converted RF signal to an input current; applying, at a current mirror (cm) stage of the circuit, the programmed gain to the input current to generate an output current; and providing, at a capacitance (c) stage of the circuit, capacitance to maintain the output current for the desired baseband signal; and providing, by the circuit, the desired baseband signal associated with the second frequency to an analog-to-digital converter (ADC).

Aspect 18: The method of Aspect 17, wherein programming the gain associated with the circuit includes: programming a resistance of the gm stage according to the first frequency associated with the down-converted RF signal; and programming a gain mode ratio associated with the cm stage according to the first frequency associated with the down-converted RF signal.

Aspect 19: The method of any of Aspects 17-18, further comprising: programming a capacitance of the gm stage to tune a first pole associated with the gm stage according to the first frequency associated with the down-converted RF signal; programming a capacitance of the cm stage to tune a second pole associated with the gm stage according to the first frequency associated with the down-converted RF signal; and programming a capacitance of the c stage to tune a third pole associated with the c stage according to the first frequency associated with the down-converted RF signal.

Aspect 20: The method of any of Aspects 17-19, further comprising: compensating, by one or more resistor-capacitor (RC) circuits included in the cm stage, droop in an output voltage associated with the cm stage.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 1-20.

Aspect 24: A computer program product comprising instructions or code for executing one or more operations recited in one or more of Aspects 1-20.

Aspect 25: A baseband filter, comprising: a transimpedance amplifier (TIA) to receive a down-converted radio frequency (RF) signal and to filter and amplify the down-converted RF signal; and one or more transconductance (gm) stages in series coupled to an output of the TIA.

Aspect 26: An apparatus, comprising: a mixer; a transimpedance amplifier (TIA) coupled to an output of the mixer; one or more transconductance (gm) stages in series coupled to an output of the TIA; and an analog-to-digital converter (ADC) coupled to an output of the one or more gm stages.

Aspect 27: The apparatus of Aspect 26, wherein the TIA is the only TIA coupled between the mixer and the ADC.

The foregoing disclosure provides illustration and description but is not intended to be exhaustive or to limit the aspects to the precise forms disclosed. Modifications and variations may be made in light of the above disclosure or may be acquired from practice of the aspects.

The foregoing outlines features of various aspects so that those skilled in the art may better understand the aspects of the present disclosure. Those skilled in the art should appreciate that the present disclosure may be readily used as a basis for designing or modifying other processes and/or structures for carrying out the same purposes and/or achieving the same advantages of the aspects described herein. Those skilled in the art should also realize that such equivalent constructions do not depart from the spirit and scope of the present disclosure, and that various changes, substitutions, and alterations may be made herein without departing from the spirit and scope of the present disclosure.

As used herein, the term “component” is intended to be broadly construed as hardware or a combination of hardware and at least one of software or firmware. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (for example, a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based on or otherwise in association with” unless explicitly stated otherwise. Also, as used herein, the term “or” is intended to be inclusive when used in a series and may be used interchangeably with “and/or,” unless explicitly stated otherwise (for example, if used in combination with “either” or “only one of”). It should be understood that “one or more” is equivalent to “at least one.”

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set.

What is claimed is:

1. A baseband filter, comprising:
a transimpedance amplifier to receive a down-converted radio frequency (RF) signal and to filter and amplify the down-converted RF signal;
a filter configured to receive the amplified down-converted RF signal and to filter the amplified down-converted RF signal to remove undesired frequency components from a desired baseband signal, wherein the filter comprises:
a first stage, associated with a first pole, to convert an input voltage associated with the amplified down-converted RF signal to an input current;
a second stage, associated with a second pole, to apply a gain to the input current to generate an output current; and
a third stage, associated with a third pole, to maintain the output current and provide the desired baseband signal to an analog-to-digital converter (ADC); and
a programming interface to receive one or more instructions to tune one or more of the first pole, the second pole, the third pole, or the gain applied to the input current based on a frequency associated with the down-converted RF signal.

2. The baseband filter of claim 1, wherein the first pole is based on a transconductance and a capacitance of the first stage.

3. The baseband filter of claim 1, wherein the second pole is based on a transconductance and a capacitance of the second stage.

4. The baseband filter of claim 1, wherein the third pole is based on a resistance of the ADC and a capacitance of the third stage.

5. The baseband filter of claim 1, wherein the one or more instructions configure a capacitance of the first stage to tune the first pole, a capacitance of the second stage to tune the second pole, or a capacitance of the third stage to tune the third pole.

6. The baseband filter of claim 1, wherein the one or more instructions configure a one or more of a resistance or a capacitance of the second stage to tune a zero that compensates for a droop associated with the desired baseband signal.

7. The baseband filter of claim 1, wherein the one or more instructions configure a bias current applied to the second stage to tune a transconductance of the second stage.

8. The baseband filter of claim 1, wherein the one or more instructions configure a resistance of the first stage to tune the gain applied to the input current.

9. A filter, comprising:
an input stage comprising a resistor-capacitor (RC) circuit configured to receive an input voltage and convert the input voltage to an input current;
a current mirror stage comprising a transistor network and one or more differential capacitors configured to receive the input current and apply a gain to the input current to generate an output current; and
an output stage comprising an output capacitor coupled between an output from the current mirror stage and an input to an analog-to-digital converter (ADC) to maintain the output current.

10. The filter of claim 9, wherein the filter is associated with a first pole based on a transconductance and a capacitance of the input stage, a second pole based on a transconductance and a capacitance of the current mirror stage, and a third pole based on a resistance of the ADC and a capacitance of the output capacitor.

11. The filter of claim 10, wherein the capacitance of the input stage, the capacitance of the current mirror stage, and the capacitance of the output capacitor are programmable to respectively tune the first pole, the second pole, and the third pole.

12. The filter of claim 10, wherein the transconductance of the current mirror stage is based on a programmable bias current applied to the current mirror stage.

13. The filter of claim 9, wherein the filter is associated with a gain based on a resistance of the ADC, a resistance of the input stage, and a gain mode ratio.

14. The filter of claim 13, wherein the resistance of the input stage and the gain mode ratio are programmable to tune the gain.

15. The filter of claim 9, wherein the current mirror stage further comprises one or more RC circuits configured to compensate droop in an output voltage associated with the current mirror stage.

16. The filter of claim 15, wherein the filter is associated with a zero based on a resistance and a capacitance of the one or more RC circuits.

17. A method, comprising:
receiving a down-converted radio frequency (RF) signal at a circuit;
programming a gain associated with the circuit according to a first frequency associated with the down-converted RF signal; and
filtering, by the circuit, the down-converted RF signal to remove undesired frequency components from a desired baseband signal associated with a second frequency, wherein filtering the down-converted RF signal includes:
converting, at a transconductance (gm) stage of the circuit, an input voltage associated with the down-converted RF signal to an input current;
applying, at a current mirror (cm) stage of the circuit, the programmed gain to the input current to generate an output current; and
providing, at a capacitance (c) stage of the circuit, capacitance to maintain the output current for the desired baseband signal; and
providing, by the circuit, the desired baseband signal associated with the second frequency to an analog-to-digital converter (ADC).

18. The method of claim 17, wherein programming the gain associated with the circuit includes:
programming a resistance of the gm stage according to the first frequency associated with the down-converted RF signal; and
programming a gain mode ratio associated with the cm stage according to the first frequency associated with the down-converted RF signal.

19. The method of claim 17, further comprising:
programming a capacitance of the gm stage to tune a first pole associated with the gm stage according to the first frequency associated with the down-converted RF signal;
programming a capacitance of the cm stage to tune a second pole associated with the gm stage according to the first frequency associated with the down-converted RF signal; and
programming a capacitance of the c stage to tune a third pole associated with the c stage according to the first frequency associated with the down-converted RF signal.

20. The method of claim 17, further comprising:
compensating, by one or more resistor-capacitor (RC) circuits included in the cm stage, droop in an output voltage associated with the cm stage.
